(19) United States
(12) Patent Application Publication
(10) Pub. No.: US 2026/0246180 A1
(43) Pub. Date: Aug. 20, 2026

(54) ELECTRICAL CONTACTOR

(71) Applicant: KABUSHIKI KAISHA NIHON MICRONICS, TOKYO (JP)

(72) Inventor: TOMOAKI KUGA, TOKYO (JP)

(21) Appl. No.: 18/876,812

(22) PCT Filed: May 18, 2023
(86) PCT No.: PCT/JP2023/018553

§ 371 Date: Dec. 19, 2024

(30) Foreign Application Priority Data
Aug. 9, 2022 (JP) 2022-126975

(51) Int. Cl. H01R 13/24; G01R 1/067; G01R 1/073; H01R 13/42

(52) U.S. Cl. CPC H01R 13/2407; G01R 1/06727; G01R 1/07307; H01R 13/42

(57) ABSTRACT

To provide an electrical contactor including a configuration provided with a spiral-structured elastic body integrally formed using a single material, and capable of as an electric circuit achieving connection without loss, in which no misalignment occurs at a contact portion. The present disclosure is intended for an electrical contactor formed of a conductive plate-shaped member, the electrical contactor including: a first wound portion formed by closely winding the plate-shaped member at a same diameter, and having one end portion including a first contact portion in contact with a first contact target; a second wound portion formed by closely winding the plate-shaped member at the same diameter, and having one end portion including a second contact portion in contact with a second contact target; and one or more spiral-structured elastic portions formed by winding the plate-shaped member at different diameters.

### TECHNICAL FIELD

The present disclosure relates to an electrical contactor, and is applicable, for example, to an electrical contactor used for a current-carrying test of an integrated circuit or inspection object on a semiconductor wafer.

### BACKGROUND ART

Inspection objects, such as an integrated circuit formed on a semiconductor wafer and a packaged integrated circuit, are subjected to an inspection of electrical characteristics at each manufacturing stage. An electrical inspection of an integrated circuit on a semiconductor wafer is conducted using an electrical connecting apparatus such as a probe card, and an electrical inspection of a packaged integrated circuit is conducted using an electrical connecting apparatus such as a socket. In such an electrical connecting apparatus, an electrical contactor is used in contact with a first contact target and a second contact target, and an electrical signal is conducted between the first contact target and the second contact target through an electrical contactor.

Conventionally, there have been various types of electrical contactors, some of which are formed by combining a plurality of components. When such an electrical contactor formed of a plurality of components is used to conduct an electrical signal between the first contact target and the second contact target, resistance becomes large at a contact point between the components, thereby affecting electrical conductivity.

Patent Document 1 discloses a spring probe with a spiral and cylindrical sleeve, a first terminal at one end of the cylindrical sleeve, and a second terminal at the other end of the cylindrical sleeve integrally molded by performing a bending process on a thin strip-shaped substrate. Such a spring probe is integrally formed from the thin strip-shaped substrate, thereby achieving favorable electrical conductivity.

### CITATION LIST

### Patent Literature

Patent Literature 1: Japanese Patent Application Laid-Open Publication No. 2011-012992.

Patent Literature 2: Japanese Patent Application Laid-Open Publication No. 2021-188984.

### SUMMARY OF INVENTION

### Technical Problem

However, when the electrical signal is conducted between the first contact target and the second contact target using the spring probe described in Patent Literature 1, an electrical conduction path in the spring probe passes through a pair of spirally wound coil springs, and therefore the path length becomes longer, which requires an improvement in the electrical conductivity.

In this regard, it is conceivable that a spiral spring (spiral-structured spring) formed by spirally winding a plate-shaped member and covering a part of an inner member thereof with an outer member thereof is used as it is as an electrical contactor, for example.

Such a spiral-structured electrical contactor described above is formed by winding one plate-shaped member, and thus it is possible to eliminate a contact point between constituent members. Therefore, it is possible to reduce a resistance value on a conduction path in the spiral-structured electrical contactor. It is also possible to shorten the path length of the conduction path in the spiral-structured electrical contactor, which is also expected to achieve favorable electrical conductivity.

Incidentally, in order to reliably ensure electrical contact between the electrical contactor and the first and second contact targets during an inspection of an inspection object, it is conceivable that the electrical contactor is configured to include elastic bodies in an up-and-down direction. Accordingly, as an electrical contactor, it is conceivable that, for example, a plate-shaped member is wound to form a spiral spring portion extending further in an upward direction than a center portion and a spiral spring portion extending further in a downward direction than the center portion in an axial direction (e.g., a connector 100 illustrated in FIG. 9).

However, when a connector 100 illustrated in FIG. 9 is inserted into a through hole 110, which is as a guide, a space (e.g., space S1 to space S4) will be produced in the through hole 110 because the connector 100 has tapered shapes respectively on upper and lower sides. The space S1 to space S4 will further be expanded at the time of contact load (FIG. 9(B)) than a housing state (FIG. 9(A)) because the spring contracts. In such a state, there is a possibility that the connector 100 may tilt (gradient G) so as to topple within the through hole 110 when the contact load is applied (FIG. 9(C)). When such tilting occurs, a misalignment occurs at a contact portion between the connector 100 and the contact target.

Thus, in view of the above-described problems, the present disclosure intends to provide an electrical contactor including a configuration provided with a spiral-structured elastic body integrally formed using a single material, and capable of as an electric circuit achieving connection without loss, in which no misalignment occurs at a contact portion.

### Solution to Problem

An aspect of the present disclosure is an electrical contactor formed by a conductive plate-shaped member, the electrical contactor including: (1) a first wound portion formed by closely winding the plate-shaped member at a same diameter, and having one end portion including a first contact portion in contact with a first contact target; (2) a second wound portion formed by closely winding the plate-shaped member at the same diameter, and having one end portion including a second contact portion in contact with a second contact target; and (3) one or more spiral-structured elastic portions formed by winding the plate-shaped member at different diameters.

### Advantageous Effects of Invention

According to the present disclosure, it is possible to provide an electrical contactor including a configuration provided with a spiral-structured elastic body integrally formed using a single material, and capable of as an electric circuit achieving connection without loss, in which no misalignment occurs at a contact portion.

### BRIEF DESCRIPTION OF DRAWINGS

FIG. 1 is a configuration diagram illustrating a configuration of a connector according to an embodiment.

FIG. 2 is a configuration diagram illustrating a configuration of an electrical connecting apparatus according to the embodiment.

FIG. 3 is an explanatory diagram illustrating a schematic formation process of the connector according to the embodiment.

FIG. 4 is an explanatory diagram illustrating a housing state of the connector according to the embodiment.

FIG. 5 is a configuration diagram illustrating a configuration of the connector before compression according to the embodiment.

FIG. 6 is an explanatory diagram illustrating advantageous effects of the connector according to the embodiment.

FIG. 7 is a configuration diagram illustrating a configuration of a connector according to a modification embodiment (first aspect).

FIG. 8 is a configuration diagram illustrating a configuration of a connector according to the modification embodiment (second aspect).

FIG. 9 is a configuration diagram illustrating a configuration of a conventional connector.

### DESCRIPTION OF EMBODIMENTS

### (A) Principal Embodiment

Hereinafter, this embodiment of an electrical contactor according to the present disclosure will be described in detail, with reference to the drawings.

This embodiment illustrates a case where the electrical contactor according to the present disclosure is applied to a connector to be mounted on an electrical connecting unit, which is a constituent member of the electrical connecting apparatus, as will be described later. The electrical contactor according to the present disclosure can be applied to any contactor configured to electrically contact a first contact target and a second contact target and capable of conducting an electrical signal between the first contact target and the second contact target. While this embodiment illustrates the case where the electrical contactor of the present disclosure is applied to the connector of the electrical connecting unit, the present disclosure can also be applied to a probe or the like configured to be connected to an electrode terminal of an inspection object.

Moreover, this embodiment illustrates a case where the electrical connecting apparatus according to the present disclosure is an electrical connecting apparatus used for an electrical inspection of an inspection object, which is an integrated circuit formed on a semiconductor wafer. The electrical connecting apparatus according to the present disclosure can be applied to an apparatus configured to conduct the electrical signal between the first contact target and the second contact target using the electrical contactor according to the present disclosure to be electrically connected therebetween.

### (A-1) Configuration of Embodiment

### (A-1-1) Electrical Connecting Apparatus

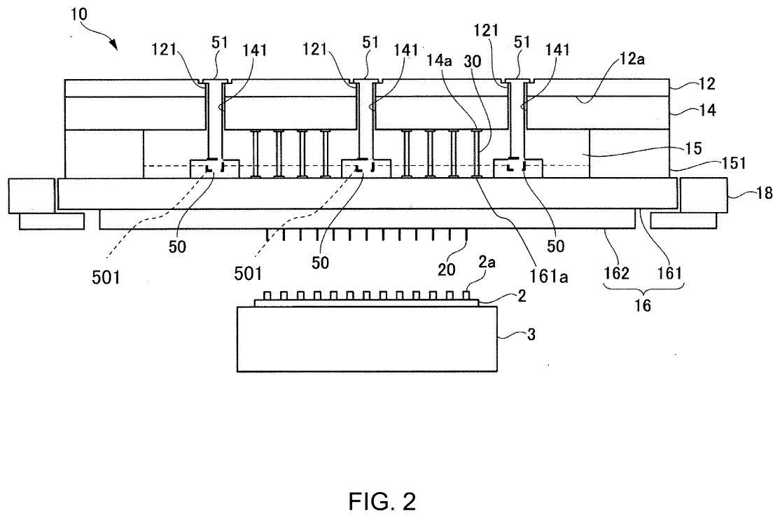

FIG. 2 is a configuration diagram illustrating a configuration of an electrical connecting apparatus according to the embodiment.

While FIG. 2 illustrates principal constituent members of the electrical connecting apparatus 10, the electrical connecting apparatus 10 is not limited to these constituent members but may actually also include constituent members not illustrated in FIG. 2. In the following description, the terms “up” or “upward” and “down” or “downward” will be mentioned with reference to the up-and-down direction in FIG. 2.

In FIG. 2, the electrical connecting apparatus 10 according to this embodiment includes a plate-shaped supporting member 12, a plate-shaped wiring board 14 held on a lower surface 12a of the supporting member 12, an electrical connecting unit 15 electrically connected to the wiring board 14, and a probe substrate 16 electrically connected to the electrical connecting unit 15 and including a plurality of probes 20.

A large number of fixation members (e.g., screwing members, such as bolts) are used to assemble the supporting member 12, the wiring board 14, the electrical connecting unit 15, and the probe substrate 16, into the electrical connecting apparatus 10, but such fixation members are not illustrated in FIG. 2.

The electrical connecting apparatus 10 conducts an electrical inspection on an inspection object 2, in which a semiconductor integrated circuit or the like formed on a semiconductor wafer is used as the inspection object 2, for example. Specifically, the inspection object 2 is electrically inspected by pressing the inspection object 2 toward the probe substrate 16, electrically contacting a tip portion of each probe 20 of the probe substrate 16 with each electrode terminal 2a of the inspection object 2, and supplying an electrical signal to the electrode terminal 2a of the inspection object 2 from a tester (inspection apparatus), which is not illustrated, and further providing an electrical signal from the electrode terminal 2a of the inspection object 2 to the tester side.

The inspection object 2, which is to be inspected, is placed on an upper surface of a chuck top 3. The chuck top 3 is capable of adjusting a position in an X-axial direction in a horizontal direction, a Y-axial direction perpendicular to the X-axial direction on a horizontal plane, and a Z-axial direction perpendicular to the horizontal plane (X-Y plane), and is further capable of adjusting a rotational posture in a θ direction around the Z axis. For implementation of an electrical inspection on the inspection object 2, a chuck capable of moving in an up-and-down direction (Z-axial direction) is moved so that each electrode terminal 2a of the inspection object 2 is electrically contacted with the tip portion of each probe 20 of the probe substrate 16. For this purpose, the lower surface of the probe substrate 16 of the electrical connecting apparatus 10 and the inspection object 2 placed on the upper surface of the chuck top 3 are moved to be relatively closer to each other.

### Supporting Member

The supporting member 12 suppresses deformation (e.g., bending or the like) of the wiring board 14. For example, since the probe substrate 16 has a large number of the probes 20, a weight of the probe substrate 16 attached to the wiring board 14 side is increased. Moreover, when conducting the electrical inspection on the inspection object 2, the probe substrate 16 is pressed against the inspection object 2 placed on the chuck top 3 such that between the tip portion of each probe 20 protruding from the lower surface of the probe substrate 16 is electrically contacted with each electrode terminal 2a of the inspection object 2. Thus, during the electrical inspection, a large load is applied also to the wiring board 14 due to action of a reaction force (contact load) pushed upward from below. The supporting member 12 functions as a member for suppressing deformation (e.g., bending or the like) of the wiring board 14.

Moreover, a plurality of through holes 121 are provided in the supporting member 12 so as to pass through between the upper surface and the lower surface thereof. Each of the plurality of through holes 121 is provided at a position corresponding to a plurality of anchors 50 disposed on the upper surface of the probe substrate 16 described below, which is a position corresponding to each of a plurality of through holes 141 provided in the wiring board 14.

A spacer (hereinafter, also referred to as a “supporter”) 51 is inserted into each through hole 121 of the supporting member 12 downward from above the supporting member 12, and is configured such that a lower end portion of the spacer (supporter) 51 can be fixed to the corresponding anchor 50. For example, the lower end portion of the spacer (supporter) 51 is a male screw portion, and a substantially center portion of the anchor 50 disposed on the upper surface of the probe substrate 16 is a female screw portion 501. The fixing can be achieved by screwing the lower end portion (male screw portion) of the spacer (supporter) 51 into the female screw portion of the anchor 50. Consequently, it is possible to maintain a distance between the upper surface of the probe substrate 16 and the upper surface of the supporting member 12 at a predetermined distance length.

### Wiring Board

The wiring board 14 is, for example, a substantially plate-shaped printed board or the like formed with a resin material such as polyimide, for example. A large number of electrode terminals (not illustrated) to be electrically connected to a test head (not illustrated) of a tester (inspection apparatus) are disposed in a peripheral edge of an upper surface of the wiring board 14. Moreover, a wiring pattern is formed on the lower surface of the wiring board 14, and a connecting terminal 14a of the wiring pattern is electrically connected to an upper end portion of the connector 30 provided in the electrical connecting unit 15.

Furthermore, a wiring circuit (not illustrated) is formed inside the wiring board 14, and the wiring pattern formed on the lower surface of the wiring board 14 and the electrode terminal formed on the upper surface of the wiring board 14 can be connected to each other through the wiring circuit formed inside the wiring board 14. Accordingly, it is possible to conduct an electrical signal through the wiring circuit in the wiring board 14 between each connector 30 of the electrical connecting unit 15, which is to be electrically connected to the connecting terminal 14a of the wiring pattern formed on the lower surface of the wiring board 14, and the test head, which is to be connected to the electrode terminal formed on the upper surface of the wiring board 14. A plurality of electronic components required for the electrical inspection conducted on the inspection object 2 are also disposed on the upper surface of the wiring board 14.

Moreover, the plurality of through holes 141 are provided in the wiring board 14 so as to pass through between the upper surface and the lower surface of the wiring board 14. Each of the plurality of through holes 141 is provided at a position corresponding to a plurality of anchors 50 disposed on the upper surface of the probe substrate 16, which is a position corresponding to each of a plurality of through holes 121 provided in the supporting member 12.

Each through hole 141 has an opening shape that can be determined in accordance with a shape of the supporter 51 to be inserted thereinto. Moreover, in order to allow each supporter 51 to be inserted into each through hole 141, an inner diameter of each through hole 141 is approximately equal to or slightly larger than an outer diameter of each supporter 51.

This embodiment illustrates a case where the opening shape of the through hole 141 is a substantially circular shape in order to illustrate a case where the supporter 51 is a circular columnar member, but the opening shape thereof is not limited to this example. For example, the supporter 51 may be a right prism member having a substantially square cross-sectional shape, a polygonal prism member having a polygonal cross-sectional shape, or the like, and even in such cases, the opening shape of the through hole 141 may be a shape that can be inserted into the supporter 51.

### Electrical Connection Unit

The electrical connecting unit 15 has a plurality of connectors 30. In an assembled state of the electrical connecting apparatus 10, an upper end portion of each connector 30 is electrically connected to each connecting terminal 14a of the wiring pattern formed on the lower surface of the wiring board 14, and a lower end portion of each connector 30 is connected to each pad provided on the upper surface of the probe substrate 16. The tip portion of the probe 20 is electrically contacted to the electrode terminal of the inspection object 2, and the electrode terminal of the inspection object 2 is electrically connected to the tester (inspection apparatus) through the probe 20 and the connector 30, and thus it is possible to electrically inspect the inspection object 2 with the tester (inspection apparatus).

For example, the electrical connecting unit 15 has a plurality of through holes (insertion holes) for inserting the connectors 30 thereinto, respectively, and the upper end portion and the lower end portion of each connector 30 protrude therefrom by inserting each connector 30 into each through hole. In the electrical connecting unit 15, a mechanism of attaching the plurality of connectors 30 is not limited to the configuration of providing the through holes, and various configurations can be widely applied. A flange part 151 is provided in a periphery of the electrical connecting unit 15.

### Probe Substrate

The probe substrate 16 is a substrate including a plurality of probes 20 provided thereon, and is formed into a substantially circular shape or a polygonal shape (e.g., hexadecagon or the like). The probe 20 may be, for example, but is not limited to, a cantilever type probe. Moreover, the probe substrate 16 has a substrate member 161 formed, for example, of a ceramic plate, and a multilayer wiring substrate 162 formed on a lower surface of the substrate member 161.

A large number of electrical conduction paths (not illustrated) passing through in a plate thickness direction are formed inside the substrate member 161, which is a ceramic substrate, a pad 161a is formed on the upper surface of the substrate member 161, and one end of the electrical conduction path in the substrate member 161 is formed so as to be connected to the corresponding pad 161a formed on the upper surface of the substrate member 161. Furthermore, on the lower surface of the substrate member 161, the other end of the electrical conduction path in the substrate member 161 is formed so as to be connected to the connecting terminal provided on the upper surface of the multilayer wiring substrate 162.

The multilayer wiring substrate 162 is formed of a plurality of multilayer substrates formed, for example, of a synthetic resin member such as polyimide, and a wiring path (not illustrated) is formed between the plurality of multilayer substrates. One end of the wiring path in the multilayer wiring substrate 162 is connected to the other end of the electrical conduction path on the substrate member 161 side, which is a ceramic substrate, and the other end of the multilayer wiring substrate 162 is connected to a probe land provided on the lower surface of the multilayer wiring substrate 162. The plurality of probes 20 are disposed on the probe land provided on the lower surface of the multilayer wiring substrate 162, and the plurality of probes 20 of the probe substrate 16 are respectively electrically connected to the corresponding connecting terminals 14a of the wiring board 14 through the electrical connecting unit 15.

### (A-1-2) Connector (Electrical Contactor)

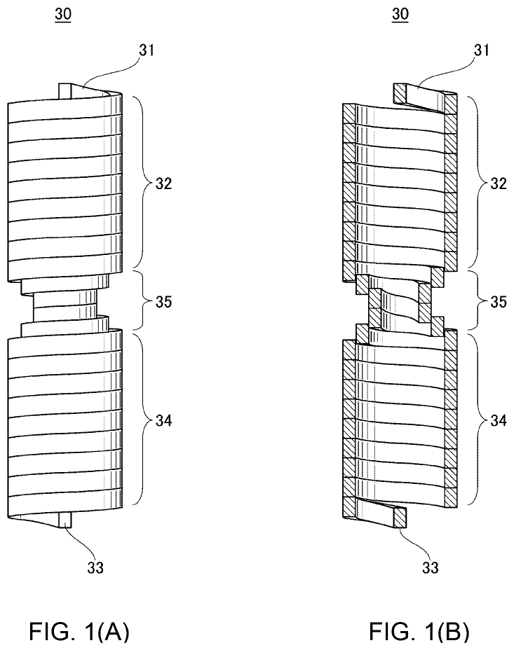

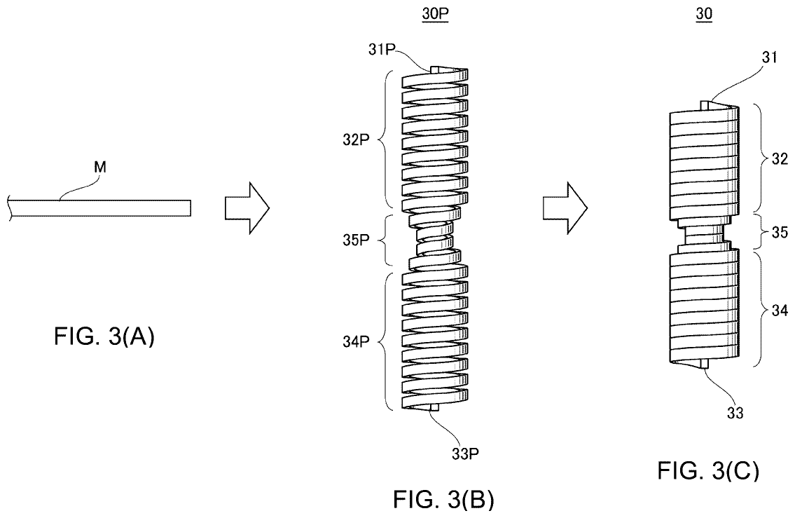

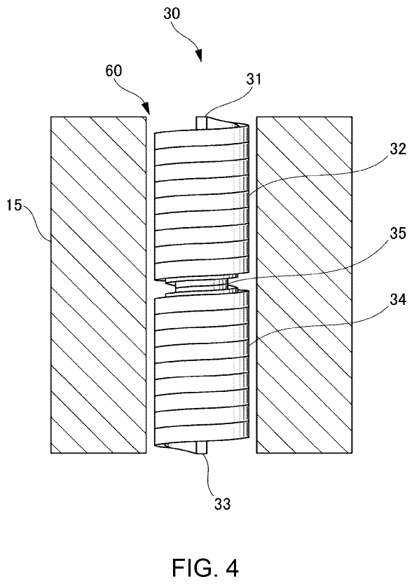

FIG. 1 is a configuration diagram illustrating a configuration of a connector according to an embodiment. FIG. 1(A) illustrates an outer appearance of the connector 30, and FIG. 1(B) illustrates a vertical cross section of the connector 30. FIG. 3 is an explanatory diagram illustrating a schematic formation process of the connector according to the embodiment. FIG. 4 is an explanatory diagram illustrating a housing state of the connector according to the embodiment.

The connector 30 illustrated in FIG. 1 is made by molding a plate-shaped member M illustrated in FIG. 3(A), forming a connector 30P having a shape before an intended shape (before compression) as illustrated in FIG. 3(B), and the forming a connector 30 having the intended shape (spirally wound spring structure in the center portion) as illustrated in FIG. 3(C) by using a compression and hardening treatment described below. The plate-shaped member M illustrated in FIG. 3 is a member before the molding process of the connector 30 (connector 30P) illustrated in FIG. 1, which is a plate-shaped member formed of a conductive material. Namely, the connector 30 is integrally formed of the single plate-shaped member so that the upper and lower portions are cylindrical and the center portion is spiral-shaped, through a plurality of processes, thereby stabilizing the conductivity of electrical signals. In other words, in a case of an electrical contactor formed by combining a plurality of components, the plurality of components come into contact with one another to conduct electrical signals, and thus a resistance becomes high at contact points between the plurality of components, which may make the conductivity unstable. In contrast, the connector 30 formed by molding the plate-shaped member M has no contact point between components, thereby making it possible to reduce the resistance value and to stabilize the conductivity of the electrical signal.

As illustrated in FIG. 1, the connector 30, which is an example of the electrical contactor, includes a first contact portion 31 in contact with the connecting terminal 14a of the wiring board 14 as a first contact target, an upper wound portion 32 that connects the first contact portion 31 and a central elastic portion 35, a second contact portion 33 in contact with the pad 161a of the substrate member 161 as a second contact target, a lower wound portion 34 that connects the second contact portion 33 and the central elastic portion 35, and a central elastic portion 35 having a spirally wound spring structure that elastically urges in an up-and-down direction via the upper wound portion 32 and the lower wound portion 34 when the first contact portion 31 and the second contact portion 33 receive a load.

The first contact portion 31 has a tip end surface in contact with the first contact target, and the aforementioned tip end surface extends diagonally upward. The second contact portion 33 has a tip end surface in contact with the second contact target, and the aforementioned tip end surface extends diagonally downward. Shapes of the first contact portion 31 and the second contact portion 33 are not limited and may be formed by various processing processes. In the connector 30, positions of the tip end surface of the first contact portion 31 and the tip end surface of the second contact portion 33 are not particularly limited, but may be disposed, for example, on the same axis in the up-and-down direction.

The upper wound portion 32 and the lower wound portion 34 are formed by winding the plate-shaped member M at the same diameter. The wound layers of the upper wound portion 32 and the lower wound portion 34 are in close contact with one another from above and below, as is clear from FIG. 1(B).

An outer diameter of the upper wound portion 32 and the lower wound portion 34 is not particularly limited, and the outer diameter is preferably an approximate value of an inner diameter of the through hole 60 (approximately the same as the inner diameter of the through hole 60) so that the connector 30 can be inserted into the through hole 60 (the through hole for inserting the connector 30) provided in the electrical connecting unit 15 illustrated in FIG. 4. This is to eliminate an occurrence of a space within the through hole 60 and to prevent the connector 30 from toppling (tilting).

The central elastic portion 35 is formed by spirally winding the plate-shaped member M and covering a part of the wound inner member with the outer member. Moreover, the central elastic portion 35 has a spiral shape that is vertically target structure. The central elastic portion 35 acts as an elastic body (spring) due to this spiral structure.

The central elastic portion 35 having the spirally wound spring structure is disposed at the center portion of the connector 30, thereby making it possible to use the upper wound portion 32 and the lower wound portion 34, which are wound at the same diameter, as a guide when the spring strokes upward and downward, thereby enabling stable contact with reduced misalignment at the contact point.

Various types of plate-shaped members, such as plate-shaped members made of precious metal or metal having electrical conductivity, are applicable to the plate-shaped member M illustrated in FIG. 3(A). For example, precipitation-hardened copper alloy such as Cu-Be based alloy (beryllium copper) is preferred as a material having high spring performance. The precipitation-hardened copper alloy is prepared by performing aging treatment on a solution-treated supersaturated solid solution. As a result, fine precipitates are uniformly dispersed to increase a strength of the alloy, while the content of a solid solution element in copper is reduced to improve electrical conductivity. Moreover, a palladium alloy is preferred as the plate-shaped member M, as is the precipitation-hardened copper alloy.

A connector 30P illustrated in FIG. 3(B) is a connector, having a shape before an intended shape, formed by molding the plate-shaped member M. The connector 30P includes a structure corresponding to each structure part of the connector 30 described above. Namely, as illustrated in FIG. 3(B), the connector 30P includes a first contact portion 31P, an upper wound portion 32P, a second contact portion 33P, a lower wound portion 34P, and a central elastic portion 35P.

A difference between the connector 30 and the connector 30P is that the connector 30P is in a state where the wound plate-shaped member M is not overlapped in each layer (state of before compression).

In this embodiment, in order to form the connector 30 having the intended shape (spirally wound spring structure at the center portion), the connector 30P before the compression illustrated in FIG. 3(B) is first formed from the plate-shaped member M illustrated in FIG. 3(A), and then the connector 30 illustrated in FIG. 3(C) is formed by using a compression and hardening treatment described below. Hereinafter, a method of manufacturing the connector 30 will be described.

### Method of Manufacturing Connector

First, the method described in Patent Literature 2 (paragraphs “0048” to “0065”) can be applied as a procedure for manufacturing the connector 30. Namely, the connector 30P is first formed from the plate-shaped member M using a coiling machine.

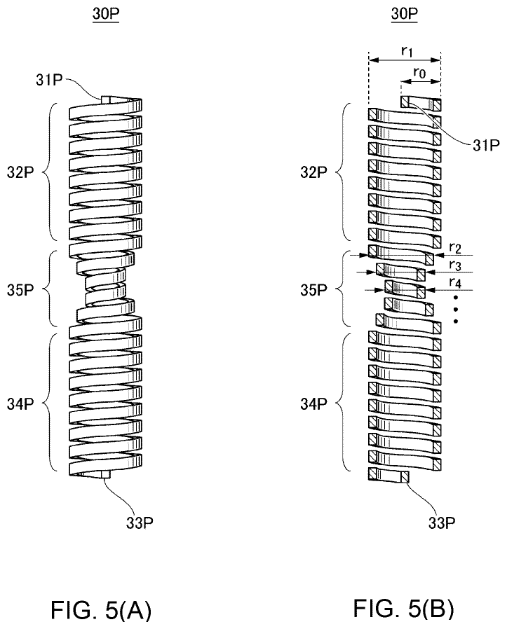

FIG. 5 is an explanatory diagram illustrating a configuration of the connector before compression according to the embodiment. FIG. 5(A) illustrates an outer appearance of the connector 30P, and FIG. 1(B) illustrates a vertical cross section of the connector 30P.

The upper wound portion 32P has a spiral structure (layered structure) around which the plate-shaped member M is wound at the same spiral diameter r1, as illustrated in FIG. 5(B).

In contrast, in the central elastic portion 35P, each time the plate-shaped member M is gradually wound, the spiral diameter r is gradually reduced (spiral shapes r2, r3, and r4) from a spiral diameter r1 of the upper wound portion 32P, and then the spiral diameter r is gradually increased from in the middle thereof (from the center point of the connector 30P). FIG. 5 illustrates an example in which the central elastic portion 35P has the spiral structure that is the vertically symmetrical relationship from the center portion, but the spiral diameter r of each spiral layered structure are not always required to be vertically symmetrical relationship as illustrated in FIG. 5, and the spiral layered structures are not always required to be the same as each other.

The lower wound portion 34P has a spiral structure around which the plate-shaped member M is wound at the same spiral diameter r1, as illustrated in FIG. 5(B).

The first contact portion 31 of the upper wound portion 32 and the second contact portion 33 of the lower wound portion 34P are processed so as to have a predetermined length (e.g., a spiral diameter r0 which is half the spiral diameter r1) after the plate-shaped member M is removed from the coiling machine.

In this embodiment, the connector 30P (the upper wound portion 32P and the lower wound portion 34P) is formed to have a vertically symmetrical spiral structure via the central elastic portion 35P, but the upper wound portion 32P and the lower wound portion 34P are not always required to be formed with such a vertically symmetrical spiral structure. For example, the spiral diameter r of the upper wound portion 32P and the lower wound portion 34P need not be the same on the top and bottom, and the spiral layered structures are not always required to be the same as each other.

Subsequently, the connector 30P is subjected to a hardening treatment (heat treatment) in a compressed state, thereby manufacturing the connector 30. The specific method of the compression and hardening treatment is similar to the procedure described in Patent Literature 2, and therefore a detailed description thereof is omitted in this regard.

### (A-2) Advantageous Effects of Embodiment

As described above, according to this embodiment, it is possible to produce the following advantageous effects.

The connector 30 of this embodiment includes the spirally wound spring (central elastic portion 35) at the center portion, and the upper wound portion 32 and the lower wound portion 34, which are closely wound at the same diameter upward and downward. Thus, when the connector 30 is stroked up and down during the contact operation, the upper wound portion 32 and the lower wound portion 34, which have a diameter approximately the same as the inner diameter of the through hole 60, slide along the through hole 60, thereby obtaining stable and reproducible contact (enabling stable contact with reduced misalignment).

Moreover, the connector 30 manufactured by the above-described manufacturing method has the spirally wound spring structure integrally formed of the single material, thereby achieving connection without loss as an electric circuit.

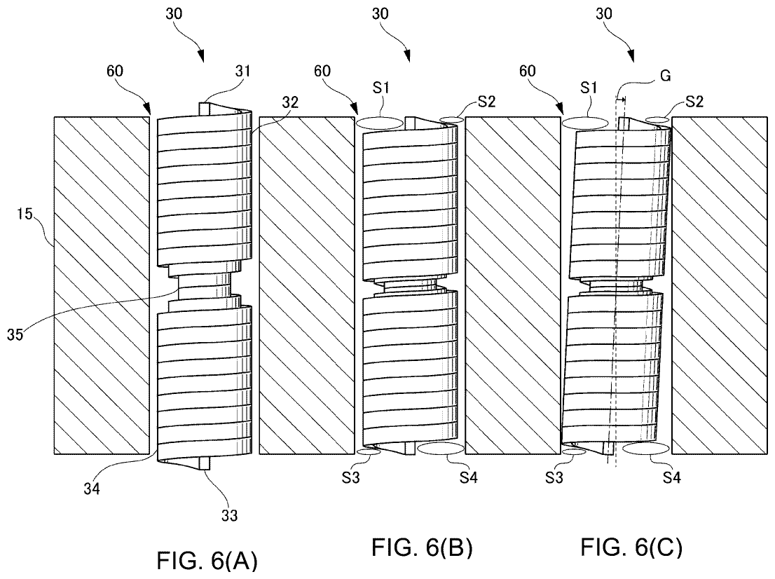

FIG. 6 is an explanatory diagram illustrating advantageous effects of the connector according to the embodiment. FIG. 6(A) illustrates a state where the connector 30 is inserted into the through hole 60 of the electrical connecting unit 15. Moreover, FIG. 6(B) illustrates a state where the central elastic portion 35 of the connector 30 is contracted due to a contact load. Furthermore, FIG. 6(C) illustrates a state where the connector 30 is tilted (gradient G) from the contracted state illustrated in FIG. 6(B). In FIG. 6(B) and 6(C), the reference signs of each component (the first contact portion 31, the upper wound portion 32, the second contact portion 33, the lower wound portion 34, the central elastic portion 35) of the connector 30 illustrated in FIG. 6(A) are omitted in order to make the drawings easier to understand.

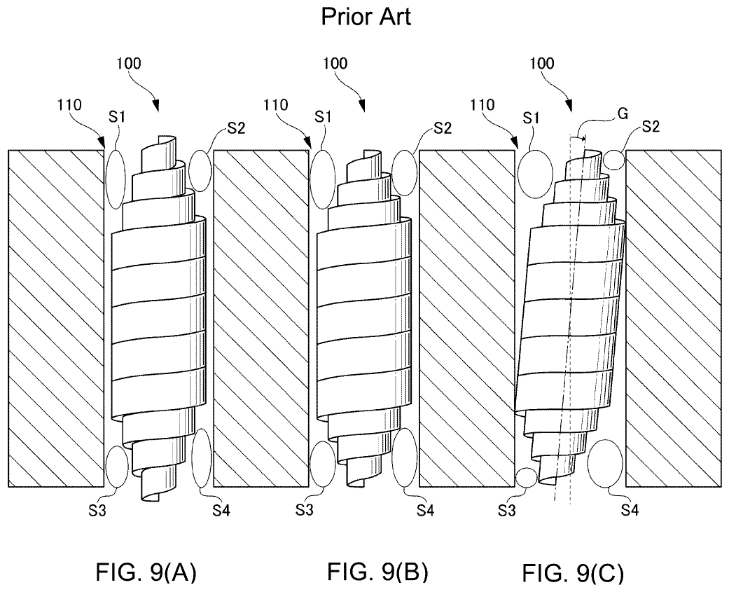

The connector 30 illustrated in FIG. 6 and the conventional connector 100 illustrated in FIG. 9 are approximately the same in size. For example, the longitudinal lengths of the connector 30 and the conventional connector 100 are approximately the same (stroke lengths are also approximately the same). The outer diameters of the upper wound portion 32 of the connector 30 and the lower wound portion 34 are approximately the same as the outer diameters of the body portion of the conventional connector 100, and the diameter of the through hole 60 illustrated in FIG. 6 is approximately the same as the through hole 110 illustrated in FIG. 11.

It is shown that the gradient G of the connector 30 illustrated in FIG. 6(C) shown under the conditions described above is smaller than the gradient G of the conventional connector 100 illustrated in FIG. 9(C). Namely, since the gradient G of the connector 30 illustrated in FIG. 6(C) is equal to or less than at least half of the gradient G of the conventional connector 100 illustrated in FIG. 9(C), it is possible to achieve a stable contact with reduced misalignment between the contact portions as compared with the conventional connector. This is because there are smaller gaps produced by spaces (space S1 to space S4) in the through hole 60 of the connector 30 even when a contact load is applied as compared with the conventional connector 100.

In order to explain in FIG. 6(C) the difference from the conventional connector 100 in FIG. 9(C), the outer diameters of the upper wound portion 32 and the lower wound portion 34 of the connector 30 are set to be approximately the same as the outer diameter of the body portion of the conventional connector 100. However, the closer the outer diameters of the upper wound portion 32 and the lower wound portion 34 of the connector 30 are to the diameter of the through hole 60, the less gradient G will occur inside the through hole 60. Namely, when the outer diameters of the upper wound portion 32 and the lower wound portion 34 of the connector 30 are set to be approximately the same as the diameter of the through hole 60, there is no gap produced by the space inside the through hole 60, the gradient G is approximately zero.

### (B) Other Embodiments

While modifications of the present disclosure are referred to also in the embodiment described above, the present disclosure is also applicable to the following embodiments.

(B-1) The embodiment described above illustrates the example in which the outer diameters of the upper wound portion 32 and the lower wound portion 34 of the connector 30 are the same as each other, but it is not limited to this example. The following are modified examples.

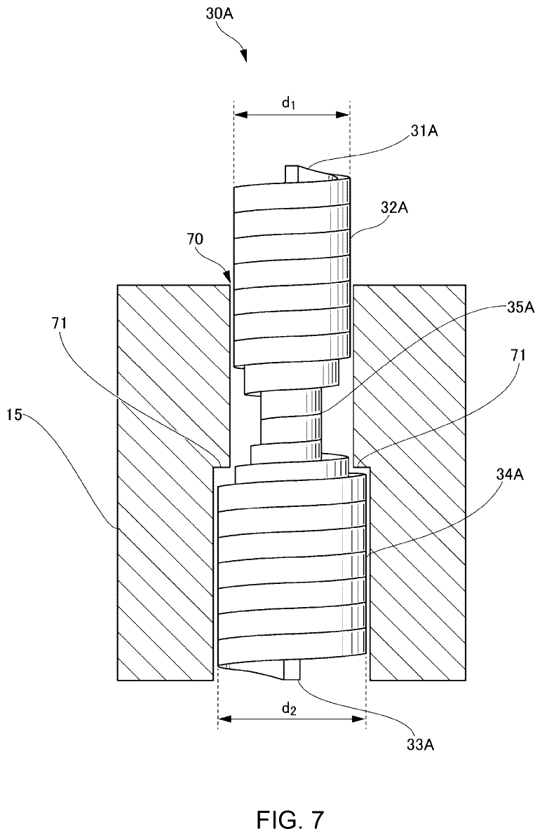

FIG. 7 is a configuration diagram illustrating a configuration of a connector according to a modification embodiment (first aspect). The connector 30A includes a structure corresponding to each structure part of the connector 30 described above. Namely, as illustrated in FIG. 7, The connector 30A includes a first contact portion 31A, an upper wound portion 32A, a second contact portion 33A, a lower wound portion 34A, and a central elastic portion 35A.

A difference between the connector 30 and the connector 30A is that the outer diameters of the upper wound portion 32A and the lower wound portion 34A are different from each other. Namely, the outer diameter d2 of the lower wound portion 34A is larger than the outer diameter d1 of the upper wound portion 32A.

In the example illustrated in FIG. 7, a through hole 70 for inserting the connector 30A is provided in the electrical connecting unit 15, and the connector 30A is inserted into the through hole 70. The inner diameter of the upper through hole 70 is slightly larger than or approximately equal to the outer diameter d1 of the upper wound portion 32A. Moreover, the inner diameter of the lower portion of the through hole 70 is slightly larger than the inner diameter of the upper portion of the through hole 70, and a stepped portion 71 is provided on an inner surface of the through hole 70. The lower wound portion 34A of the inserted connector 30 is caught on the stepped portion 71 on the inner surface of the through hole 70. The outer diameter d2 of the lower wound portion 34A is approximately the same as the inner diameter of the lower through hole 70 so that the lower wound portion 34A is caught on (is in contact with) the stepped portion 71.

As described above, the connector 30A of the modified embodiment is configured such that the outer diameter d2 of the lower wound portion 34A is larger than the outer diameter d1 of the upper wound portion 32A and the lower wound portion 34A is in contact with (is caught on) the stepped portion 71 of the through hole 70, thereby serving as a spring retainer even during the contact operation.

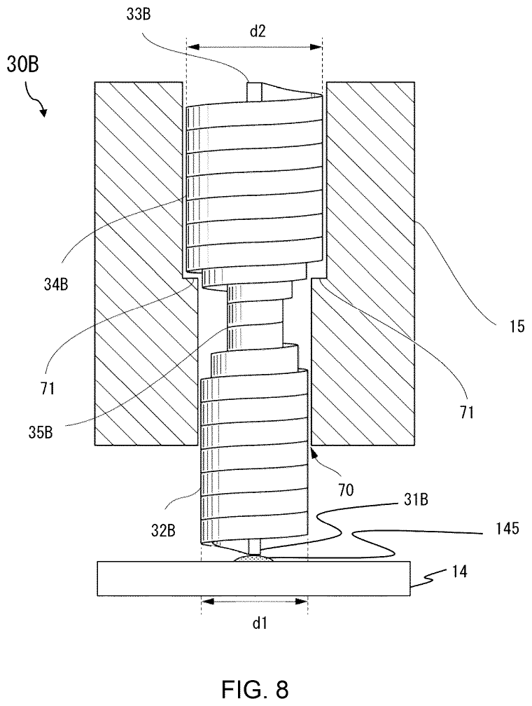

(B-2) A connector 30B can be illustrated in FIG. 8 as a modified example of the connector 30. The connector 30B has a configuration upside down compared to the connector 30A described above (since each component corresponds to that in FIG. 7, description of details is omitted). FIG. 8 illustrates a case where the above-described wiring board 14 is disposed below the connector. During the contact operation, the lower wound portion 34B is caught on the stepped portion 71, thereby preventing the connector 30B from falling downward, and also preventing the connector 30B from tilting, thereby allowing the first contact portion 31B to be reliably contacted with the electrode pad 145 disposed on the wiring board 14.

(B-3) In the above embodiment, the connector 30 has one spiral spring structure disposed at the center portion, but it is not limited to this example. Namely, there may be a plurality of spiral spring structures as elastic bodies. In this case, a connecting portion having a structure wound at the same diameter, such as the upper wound portion 32 or the lower wound portion 34, may be provided between each spiral spring structure. According to such a configuration, it is possible to increase the stroke length of the spring.

### Reference Signs List

30, 30P, 30A, 30B: Connector;
31, 31P, 31A, 31B: First contact portion;
32, 32P, 32A, 32B: Upper wound portion;
33, 33P, 33A, 33B: Second contact portion;
34, 34P, 34A, 34B: Lower wound portion;
35, 35P, 35A, 35B: Central elastic portion;
60, 70: Through hole;
71: Stepped portion; and
M: Plate-shaped member.

1. An electrical contactor formed of a conductive plate-shaped member, the electrical contactor including:
a first wound portion formed by closely winding the plate-shaped member at a same diameter, and having one end portion including a first contact portion in contact with a first contact target;
a second wound portion formed by closely winding the plate-shaped member at the same diameter, and having one end portion including a second contact portion in contact with a second contact target; and
one or more spiral-structured elastic portions formed by winding the plate-shaped member at different diameters.

2. The electrical contactor according to claim 1, wherein outer diameters of the first wound portion and the second wound portion are approximately the same as an inner diameter of a through hole for inserting the electrical contactor.

3. The electrical contactor according to claim 2, wherein
one inner diameter of the through hole is larger than the other inner diameter of the through hole, a stepped portion on which the second wound portion is caught is provided on an inner surface of the through hole,
the outer diameter of the first wound portion is approximately the same as the one inner diameter of the through hole, and
the outer diameter of the second wound portion is approximately the same as the other inner diameter of the through hole.
